(19) United States
(12) Patent Application Publication
(10) Pub. No.: US 2007/0182023 A1
(43) Pub. Date: Aug. 9, 2007

(54) Semiconductor device

(75) Inventors: Shinji Hiramitsu, Kashiwa (JP); Satoshi Matsuyoshi, Takahagi (JP); Koji Sasaki, Mito (JP); Takeshi Terasaki, Mito (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hitachi, Ltd., Tokyo (JP)

(21) Appl. No.: 11/654,051

(22) Filed: Jan. 16, 2007

(30) Foreign Application Priority Data
Feb. 8, 2006 (JP) 2006-030393

(51) Int. Cl. H01L 23/48

(52) U.S. Cl. 257/778

(57) ABSTRACT

By making coefficients of linear thermal expansion of stress relief members on upper and lower surface sides of a semiconductor chip small, thermal strain on joint members above and below the semiconductor chip is decreased and development of a crack therein is suppressed to ensure a joint area. Furthermore, by making areas of electrodes and stress relief members large enough to include a project plane of the semiconductor chip projected onto the joint surfaces thereof, even if a crack develops into the joint member between the stress relief member and the electrode, a joint area larger than the area of the semiconductor chip can be ensured for a certain amount of time. As a result, a semiconductor device capable of simultaneously ensuring the joint areas of the respective joint members and preventing a decrease in heat release capability is provided.

### CROSS-REFERENCE TO RELATED APPLICATION

The present application claims priority from Japanese Patent Application No. JP 2006-030393 filed on Feb. 8, 2006, the content of which is hereby incorporated by reference into this application.

### TECHNICAL FIELD OF THE INVENTION

The present invention relates to a vehicle-mounted semiconductor device for converting an alternating current to a direct current.

### BACKGROUND OF THE INVENTION

The device according to the present invention is a vehicle-mounted semiconductor device mounted on an alternating-current generator of an automobile and having a rectification function of converting an alternating current output to a direct current output. FIG. 6 is a cross-sectional view of a state of mounting of a conventional vehicle-mounted semiconductor device. In FIG. 6, 1 denotes a semiconductor chip, 2 denotes a joint member that joins the semiconductor chip 1 and a stress relief member 3 together, 3 denotes the stress relief member for relaxing thermal strain of the joint member 2 and a joint member 4, 4 denotes the joint member that joins the stress relief member 3 and a case electrode 5 together, 5 denotes the case electrode, 6 denotes a joint member that joins the semiconductor chip 1 and a lead electrode 9 together, 9 denotes the lead electrode having a header portion of lead electrode 9a with a diameter larger than a lead for the purpose of joining with the joint member 6, and 10 denotes a dielectric member for protecting the surface of the semiconductor chip 1. 11 denotes a mounting heat sink for holding the case electrode 5, 12 denotes a mounting terminal connecting to the lead electrode 9, 13 denotes a terminal block supporting the mounting terminal 12 and fixed to the heat sink 11. In this semiconductor device, since the incorporated semiconductor chip 1 is heated through energization, heat releasing routes for that heat have to be ensured. In this structure, there are routes including: a route for conveying heat from the semiconductor chip 1 to the joint member 2, the stress relief member 3, the joint member 4, and then the case electrode 5, and finally dissipating heat to the heat sink 11;and a route for conveying heat from the semiconductor chip 1 to the joint member 6 and then the lead electrode 9 and finally dissipating heat to the mounting terminal 12 (for example, refer to Japanese Patent Application Laid-Open Publication No. 2002-359328). Also, in one example, in order to increase heat radiation from the header portion of lead electrode, the diameter of the header portion of lead electrode is increased (for example, refer to Japanese Patent Application Laid-Open Publication No. 58-111353).

In the semiconductor device, the incorporated semiconductor chip 1 is heated through energization. In addition, being mounted on an engine room of an automobile, the semiconductor device is extremely susceptible to an influence of heating at other electrical components mounted on the vehicle. Moreover, the automobile itself is used under a severe environment receiving repeated temperature increases and decreases over a wide temperature range, such as temperature differences in midsummer. Receiving such repeated thermal impacts, thermal strain due to a difference in coefficient of linear thermal expansion of the components of the semiconductor device is exerted on the joint members 2, 4, and 6, thereby causing and developing a crack from ends of these joint members 2, 4, and 6. With such a development of a crack, the joint areas of the joint members 2, 4, and 6, which are energization routes, are decreased to increase electrical resistance, thereby increasing the amount of heating. Also, the areas of the heat radiating routes through the joint members 2, 4, and 6 are decreased to decrease heat release capability, thereby abnormally increasing the temperature of the semiconductor chip 1. Eventually, the joint members 2, 4, and 6 are melted, and the semiconductor chip 1 reaches a heat-resistance limit, thereby causing a loss of the rectification function and also causing a failed state.

### SUMMARY OF THE INVENTION

For the above problems, the inventors focused attention to the fact that heat from the semiconductor chip 1 at the time of energization of the semiconductor device is radiated from the lead electrode and the case electrode to the outside of the device, and found that what influences heat release capability on the heat radiating routes most is the joint areas of the joint members 2 and 6 facing the semiconductor chip 1 and that the influences of the joint areas of the joint members 4 and 8 located away from the semiconductor chip 1 are relatively small. Therefore, it is found that, in the semiconductor device, a desirable structure is such that a crack does not develop in the joint members 2 and 6 facing the semiconductor chip 1 even with repeated terminal impacts, and moreover the joint areas of the joint members 4 and 8 located away from the semiconductor chip 1 are ensured to some degree even if a crack develops therein.

The present invention is a vehicle-mounted semiconductor device including a first stress relief member disposed between a semiconductor chip and a header portion and a first joint member that joins the header portion and the first stress relief member, wherein a joint area of the first joint member is ensured even if a crack develops in the first joint member.

According to the present invention, even if a crack develops in a joint member 4 between a stress relief member 3 and a case electrode 5, and a joint member 8 between a stress relief member 7 and a lead electrode 9, the joint area larger than the area of a semiconductor chip 1 can be ensured until the development of the crack proceeds to some degree. As a result, a semiconductor device with ensured joint areas of joint members 2, 4, 6, and 8 and a suppressed decrease in heat release capability can be provided.

### BRIEF DESCRIPTIONS OF THE DRAWINGS

FIG. 1 is a cross-sectional view of a semiconductor device according to a first embodiment of the present invention;

FIG. 2 is a cross-sectional view of a semiconductor device according to a second embodiment of the present invention;

FIG. 3 is a graph showing a relation between an outer diameter of an initial joint portion of a joint member 8 and the number of cycles required until a crack on the joint member 8 reaches a position 1.0 mm away from an end face of a semiconductor chip 1;

FIG. 4 is a graph showing a relation between thermal strains of a joint member 2 under the semiconductor chip 1 and a joint member 4 above a case electrode 5 and coefficients of linear thermal expansion of stress relief members 3 and 7;

FIG. 5 is a graph showing a relation between the ratios of thermal strains of a joint member 2 under the semiconductor chip 1 and the joint member 4 above the case electrode 5 and the coefficients of linear thermal expansion of the stress relief members 3 and 7; and

FIG. 6 is a drawing of a mounted state of a conventional semiconductor device.

### DESCRIPTIONS OF THE PREFERRED EMBODIMENTS

### First Embodiment

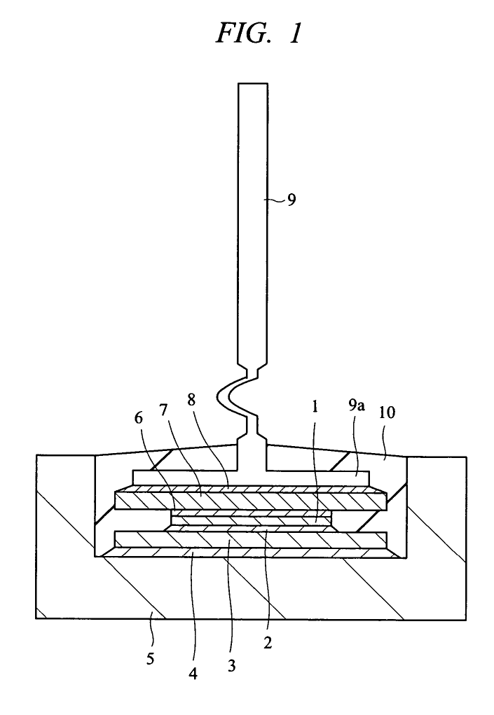

A first embodiment of the present invention is described with reference to FIG. 1. A semiconductor device shown in FIG. 1 includes a semiconductor chip 1, a stress relief member 3 which is a second conductive member disposed via a joint member 2 (solder) on a lower surface side of the semiconductor chip 1, a case electrode 5 disposed via a joint member 4 on a further lower side of the stress relief member 3 on the lower surface side of the semiconductor chip 1, a stress relief member 7 which is a first conductive member disposed via a joint member 6 on an upper side of the semiconductor chip 1, a lead electrode 9 having a header portion of lead electrode 9a disposed via a joint member 8 on a further upper surface side of a stress relief member 7 on the upper surface side of the semiconductor chip 1, the header portion of lead electrode 9a having a diameter larger than the lead for the purpose of bonding with the joint member.

The semiconductor chip has a rectification function used for the functions of the semiconductor device. The stress relief members 3 and 7 are formed of conductive members, and each has a coefficient of linear thermal expansion of 3×10⁻⁶/° C. to 10×10⁻⁶/° C., thereby acting as members that decrease a stress on the semiconductor chip 1 and the joint members 2 and 6. Also, the stress relief member 7, the header portion of lead electrode 9a, the joint member 8 therebetween on the upper surface side of the semiconductor chip 1 and the stress relief member 3 and the joint member 4 on the lower surface side of the semiconductor chip 1 are larger than the semiconductor chip 1, thereby increasing heat release capability of both of above and below the semiconductor chip 1. As for the shapes of the semiconductor chip 1, the stress relief members 3 and 7, and the header portion of lead electrode 9a viewed from above, any structure is within an applicable range of the present invention, as long as the electrodes 5 and 9 and the stress relief members 3 and 7 are larger than the semiconductor chip 1, and the ends of the joint member 4 between the electrode 5 and the stress relief member 3 and the ends of the joint member 8 between the electrode 9 and the stress relief member 7 are located outside of a project plane of the semiconductor chip 1. If the structure is within such an applicable range, the header portion of lead electrode 9a, the case electrode 5, and the stress relief members 3 and 7 all have a size that covers the project plane of the semiconductor chip 1.

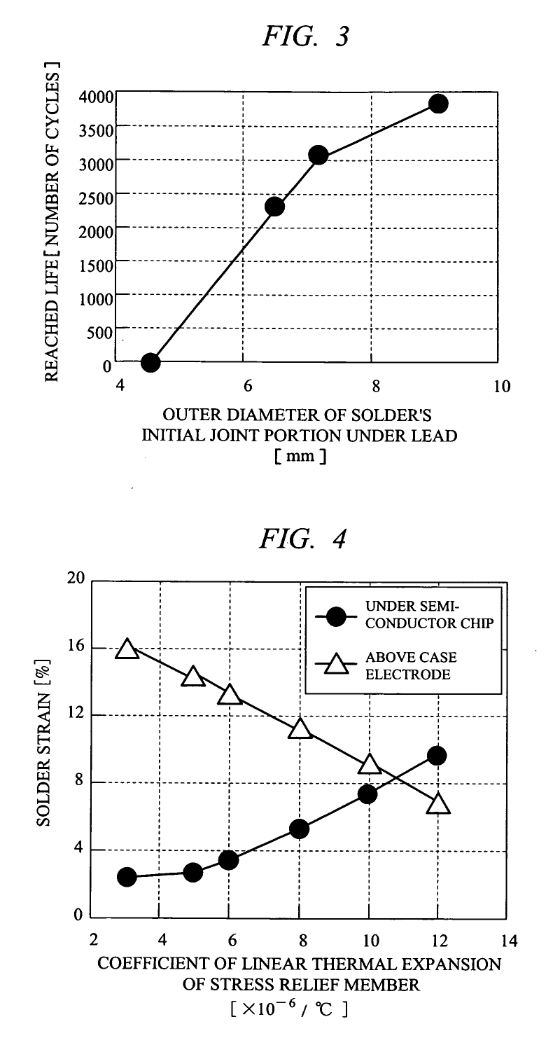

First, an effect of placing the ends of: the stress relief member 7, the header portion of lead electrode 9a, and the joint member 8 therebetween on the upper surface side of the semiconductor chip 1; and the stress relief member 3 and the joint member 4 on the lower surface side of the semiconductor chip 1 outside the project plane of the end face of the semiconductor chip 1 is described. FIG. 3 is a graph showing a relation between an outer diameter of an initial joint portion of the joint member 8 and the number of cycles required until a crack of the joint member 8 between the stress relief member 7 and the lead electrode 9 reaches a position 1.0 mm away from an end face of an area formed by projecting the semiconductor chip 1 onto the surface of the joint member 8 in a solder crack development analysis where the ambient temperature is changed from 50° C.→182° C.→50° C. with the use of an analytical model in which the stress relief member 7, the header portion of lead electrode 9a, the joint member 8 therebetween on the upper surface side of the semiconductor chip 1 and the stress relief member 3 and the joint member 4 on the lower surface side thereof are all in a disc shape. It can be recognized that, the larger the joint area of the joint member 8 below the lead electrode 9 is, the more the number of cycles is increased for a crack to reach a position 1.0 mm away from an end face of the semiconductor chip 1. That is, with a large outer diameter of the joint member 8, the time when a crack in the joint member 8 develops to enter the inside of the end face of the project plane of the semiconductor chip 1 comes later.

As for heat release capability of the semiconductor chip 1, the more the areas of the header portion 9a, the stress relief members 3 and 7, and the joint members 2, 4, 6, and 8 are large, the more the heat release capability increase. The smaller the areas are, the more the heat release capability is decreased. In particular, when a crack occurs in the joint members 2, 4, 6, and 8, and the area obtained by projecting the semiconductor chip 1 onto the surface where the joint members 2, 4, 6, and 8 are present is decreased, decrease in the heat release capability becomes large. In the present invention, with the areas of the joint members 4 and 8 being large, a crack entering the area obtained by projecting the semiconductor chip 1 onto the surface where the joint members are present is suppressed. Also, a failure of the semiconductor chip 1 due to a decrease in heat release capability can be prevented, thereby achieving long life of the semiconductor device.

Also, areas immediately outside of the areas obtained by projecting the semiconductor chip 1 onto the joint members 4 and 8 have a sufficiently large influence on the heat release capability. Therefore, it is preferable that a crack to be prevented from developing into an area obtained by projecting the semiconductor chip 1 with its radius increased by 1 mm onto the joint members 4 and 8. To achieve this, it is preferable that the joint members 4 and 8 have a size so as to cover the entire area obtained by projecting the semiconductor chip 1 with its radius increased by 1 mm onto the joint members 4 and 8.

Next, an effect of setting the coefficients of linear thermal expansion of the stress relief member 7 on the upper surface side of the semiconductor chip 1 and the stress relief member 3 on the lower surface side thereof at 3×10⁻⁶/° C. to 10×10⁻⁶/° C. is described. FIG. 4 is a graph showing a relation between thermal strains of the joint member 2 under the semiconductor chip 1 and the joint member 4 above the case electrode 5 and coefficients of linear thermal expansion of the stress relief members 3 and 7 where the temperature is changed from 50° C.→182° C.→450° C. It can be realized that, the smaller the coefficients of linear thermal expansion of the stress relief members 3 and 7 are, the smaller the thermal strain of the joint member 2 under the semiconductor chip 1 is, whilst the larger thermal strain of the joint member 4 above the case electrode 5 is.

A large thermal strain means an easy development of a crack. As described above, by increasing the areas of the joint members 4 and 8, deterioration in heat release capability of the semiconductor chip 1 can be suppressed even if a crack develops in the joint members 4 and 8. However, it is difficult to increase the areas of the joint members 2 and 6 which are in direct contact with the semiconductor chip 1 so as to making these areas are larger than the semiconductor chip 1. Therefore, by adjusting the coefficients of linear thermal expansion of the stress relief members 3 and 7, instead of sacrificing development of a crack in the joint members 4 and 8, development of a crack in the joint members 2 and 6 which are in direct contact with the semiconductor chip 1 can be suppressed. As for the joint members 4 and 8, by increasing their areas as described above, it is possible to address the problem of deterioration in heat release capability due to a crack.

When the coefficients of linear thermal expansion of the stress relief members 3 and 7 are set at an intermediate value between the coefficient of linear thermal expansion of the semiconductor chip 1 and the coefficient of linear thermal expansion of the header portion 9a or the case electrode 5 (a value obtained by dividing the sum of these coefficients of linear thermal expansion by 2), an approximately equal thermal strain is exerted on the joint members 2 and 6 and the joint members 4 and 8. If the coefficients of linear thermal expansion of the stress relief members 3 and 7 are decreased, the thermal stains of the joint member 4 above the case electrode 5 and the joint member 8 below the lead electrode 9 are increased, and therefore a crack is easy to develop. On the other hand, the thermal strains of the joint members 2 and 6 near the semiconductor chip 1 are decreased, and therefore a crack is difficult to develop. For this reason, the coefficients of linear thermal expansion of the stress relief members 3 and 7 have to be adjusted to an appropriate value that is small to some degree. In the present embodiment, the lead electrode 9 and the case electrode 5 are made of copper (its coefficient of linear thermal expansion is 16.5×10⁻⁶/° C.), whilst the semiconductor chip 1 is made of silicon (its coefficient of linear thermal expansion is 3×10⁻⁶/° C.). When the coefficients of linear thermal expansion of the stress relief members 3 and 7 are set at 10×10⁻⁶/° C. which is approximately intermediate value of them or lower, the thermal strains of the joint members 2 and 6 which are closer to the semiconductor chip 1 than the joint members 4 and 8 are decreased, thereby making the joint members 2 and 6 resistant to the occurrence of a crack. Also, the lower limit is preferably set at 3×10⁻⁶/° C., which is equal to the coefficient of linear thermal expansion of the semiconductor chip. That is, the coefficient of linear thermal expansion of the stress relief member 7 is set so as to be smaller than the intermediate value between the coefficient of linear thermal expansion of the semiconductor chip 1 and the coefficient of linear thermal expansion of the header portion 9a, and be larger than the coefficient of linear thermal expansion of the semiconductor chip 1. With this, development of a crack in the joint member 6 adjacent to the semiconductor chip 1 is suppressed, thereby suppressing deterioration in heat release capability of the semiconductor chip. Also, the coefficient of linear thermal expansion of the stress relief member 3 is set so as to be smaller than the intermediate value between the coefficient of linear thermal expansion of the semiconductor chip 1 and the coefficient of linear thermal expansion of the case electrode 5, and be larger than the coefficient of linear thermal expansion of the semiconductor chip 1. With this, development of a crack on the joint member 2 adjacent to the semiconductor chip 1 is suppressed, thereby suppressing deterioration in heat release capability of the semiconductor chip.

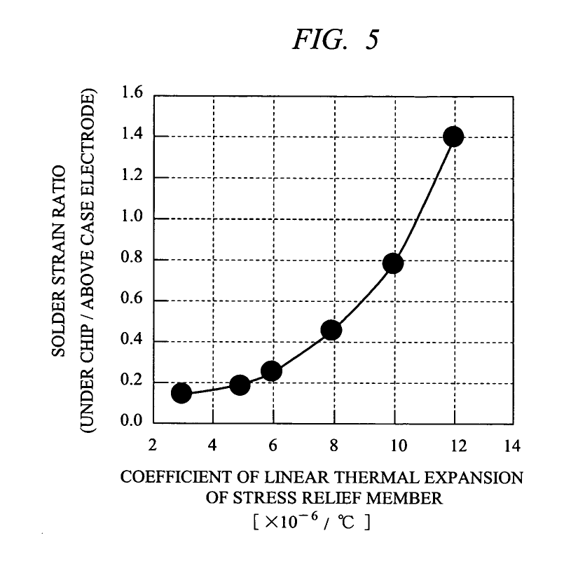

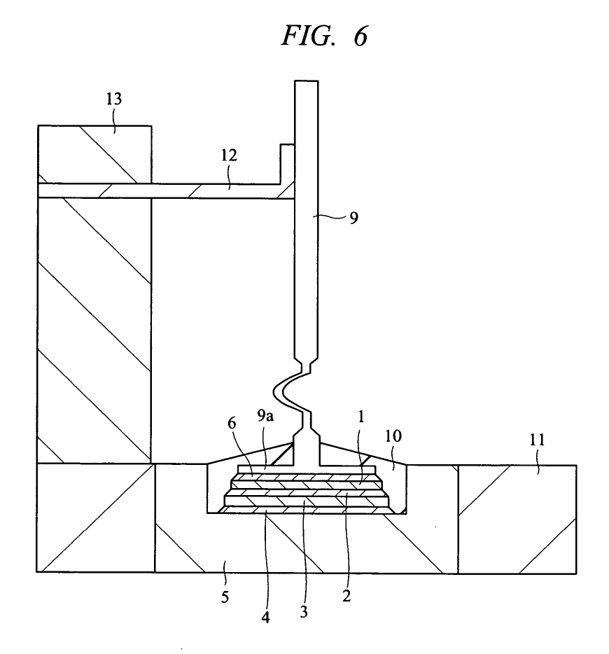

FIG. 5 is a graph showing a relation between the ratios of thermal strains of the joint member 2 under the semiconductor chip 1 and the joint member 4 above the case electrode 5 and the coefficients of linear thermal expansion of the stress relief members 3 and 7. If the coefficients of linear thermal expansion of the stress relief members 3 and 7 are 3×10⁻⁶/° C. to 10×10⁻⁶/° C., the thermal strain of the joint member 2 under the semiconductor chip 1 is smaller than the thermal strain of the joint member 4 above the case electrode 5. Therefore, crack develops in the joint member 4 above the case electrode 5 earlier than in the joint member 2. Furthermore, with such early development of a crack in the joint member 4 above the case electrode 5, the thermal strain of the joint member 2 under the semiconductor chip 1 is relaxed, thereby further making development of a crack slower.

That is, by appropriately adjusting the coefficients of thermal expansion of the stress relief member 7 on the upper surface side of the semiconductor chip 1 and the stress relief member 3 on the lower surface side thereof to 3×10⁻⁶/° C. to 10×10⁻⁶/° C., development of a crack into the joint members 4 and 2 is suppressed. In the present embodiment, although the stress relief members 3 and 7 for use are made of molybdenum (its coefficient of linear thermal expansion is 4.9×10⁻⁶/° C.), a stress relief member formed of a material having molybdenum as a main element having an approximate coefficient of linear thermal expansion may also be used. Also, a stress relief member made of another material, such as tungsten or iron-nickel alloy, may be used as long as it has the coefficient of linear thermal expansion described above.

Furthermore, preferably, the stress relief members 3 and 7 are approximately identical in shape (size, thickness, etc.) and material. That is, with the stress relief members 3 and 7 being identical components, the amounts of linear thermal expansion of these members are equal to each other, and stresses from above and below the semiconductor chip 1 due to thermal expansion are equal to each other. With this, warpage of the semiconductor chip 1 is suppressed, thereby preventing breakage due to warpage. Also, cost-down can be expected through commonality of the components of the stress relief members 3 and 7.

### Second Embodiment

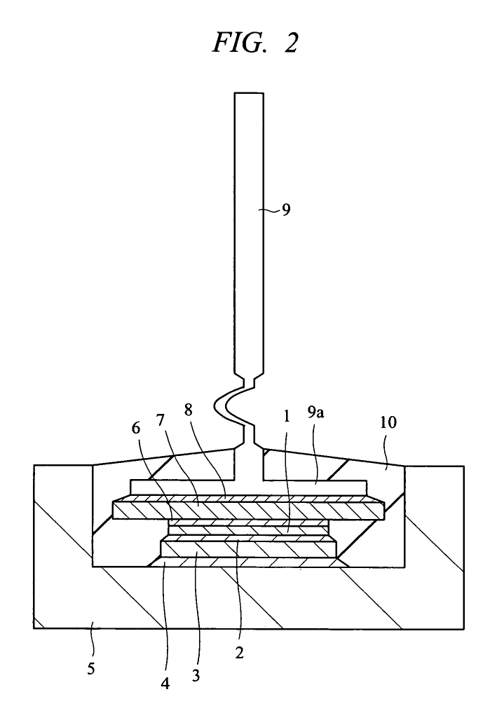

A second embodiment of the present invention is described with reference to FIG. 2. FIG. 2 depicts an example of structure in which, in a semiconductor device including a semiconductor chip 1, a stress relief member 3 disposed via a joint member 2 on a lower surface side of the semiconductor chip 1, a case electrode 5 disposed via a joint member 4 on a further lower side of the stress relief member 3 on the lower surface side of the semiconductor chip 1, a stress relief member 7 disposed via a joint member 6 on an upper side of the semiconductor chip 1, and a lead electrode 9 having a header portion of lead electrode 9a disposed via a joint member 8 on a further upper surface side of the stress relief member 7 on the upper surface side of the semiconductor chip 1, the header portion of lead electrode 9a having a diameter larger than a lead for the purpose of bonding with the joint member, the stress relief member 7 on the upper surface side of the semiconductor chip 1 and the stress relief member 3 on the lower surface side thereof have a coefficient of linear thermal expansion of 3×10⁻⁶/° C. to 10×10⁻⁶/° C. Moreover, the stress relief member 7, the header portion of lead electrode 9a, and the joint member 8 therebetween on the upper surface side of the semiconductor chip 1 are larger than the semiconductor chip 1, thereby suppressing a decrease in heat release capability on the upper side of the semiconductor chip 1. The present embodiment is effective when thermal resistance on the upper side of the semiconductor chip 1 is desired to be decreased.

What is claimed is:

1. A semiconductor device comprising:
a semiconductor chip having a rectification function;
a lead electrode having a header portion and is connected to a lead;
a case electrode;
a first stress relief member disposed between the semiconductor chip and the header portion;
a first joint member that joins the header portion and the first stress relief member together; and
a second joint member that joins the semiconductor chip and the first stress relief member together, wherein
the first joint member has an area larger than an area of the semiconductor chip.

2. The semiconductor device according to claim 1,
wherein a project plane with a circumference 1 mm outward from an end face of the semiconductor chip is included in the first joint member.

3. The semiconductor device according to claim 1, comprising:
a second stress relief member disposed between the semiconductor chip and the case electrode;
a third joint member that joins the semiconductor chip and the second stress relief member together; and
a fourth joint member that joins the case electrode and the second stress relief member together,
wherein the fourth joint member has an area larger than the area of the semiconductor chip.

4. The semiconductor device according to claim 3,
wherein a project plane with a circumference 1 mm outward from an end face of the semiconductor chip is included in the fourth joint member.

5. The semiconductor device according to claim 3,
wherein the first stress relief member and the second stress relief member are approximately identical in material and shape to each other.

6. The semiconductor device according to claim 1,
wherein the first stress relief member has a coefficient of linear thermal expansion smaller than an intermediate value between a coefficient of linear thermal expansion of the semiconductor chip and a coefficient of linear thermal expansion of the header portion.

7. The semiconductor device according to claim 1,
wherein the first stress relief member has a coefficient of linear thermal expansion of 3×10⁻⁶/° C. to 10×10⁻⁶/° C.

8. The semiconductor device according to claim 1,
wherein the first stress relief member is made of molybdenum or a material having molybdenum as a main element.

9. The semiconductor device according to claim 3,
wherein the second stress relief member has a coefficient of linear thermal expansion smaller than an intermediate value between a coefficient of linear thermal expansion of the semiconductor chip and a coefficient of linear thermal expansion of the header portion, and larger than a coefficient of linear thermal expansion of the semiconductor chip.

10. The semiconductor device according to claim 3,
wherein the second stress relief member has a coefficient of linear thermal expansion of 3×10⁻⁶/° C. to 10×10⁻⁶/° C.

11. A semiconductor device comprising:
a semiconductor chip having a rectification function;
a lead electrode having a header portion and is connected to a lead;
a case electrode;
a first stress relief member disposed between the semiconductor chip and the header portion;
a first joint member that joins the header portion and the first stress relief member together; and
a second joint member that joins the semiconductor chip and the first stress relief member together,
wherein the lead electrode and the first stress relief member are both larger in area than the semiconductor chip.

12. A semiconductor device comprising:
a semiconductor chip having a rectification function;
a lead electrode having a header portion and is connected to a lead;
a case electrode;
a first stress relief member disposed between the semiconductor chip and the header portion;
a first joint member that joins the header portion and the first stress relief member together; and
a second joint member that joins the semiconductor chip and the first stress relief member together,
wherein the first stress relief member has a coefficient of linear thermal expansion smaller than an intermediate value between a coefficient of linear thermal expansion of the semiconductor chip and a coefficient of linear thermal expansion of the header portion, and
the first joint member has an area larger than an area of the second joint member.
